(19) United States
(12) Patent Application Publication
(10) Pub. No.: US 2012/0205820 A1
(43) Pub. Date: Aug. 16, 2012

(54) ENCAPSULATING RESIN SHEET AND SEMICONDUCTOR DEVICE USING THE SAME, AND MANUFACTURING METHOD FOR THE SEMICONDUCTOR DEVICE

(75) Inventors: Takashi Oda, Ibaraki-shi (JP); Kosuke Morita, Ibaraki-shi (JP); Hiroyuki Senzai, Ibaraki-shi (JP)

(73) Assignee: NITTO DENKO CORPORATION, Osaka (JP)

(21) Appl. No.: 13/364,592

(22) Filed: Feb. 2, 2012

(30) Foreign Application Priority Data
Feb. 14, 2011 (JP) 2011-028470

(51) Int. Cl. H01L 23/522; B32B 7/02; B32B 27/38; H01L 21/56

(52) U.S. Cl. 257/778; 438/118; 428/212; 428/213; 257/E23.142; 257/E21.502

(57) ABSTRACT

Provided are an encapsulating resin sheet having improved a connection reliability by improving a connection failure, and by suppressing intrusion of an inorganic filler between terminals of the semiconductor element and the interconnection circuit substrate, a semiconductor device using the same, and a fabricating method for the semiconductor device. The encapsulating resin sheet is an epoxy resin composition sheet having a two-layer structure of an inorganic filler containing layer and an inorganic filler non-containing layer, in which a melt viscosity of the inorganic filler containing layer is 1.0×10² to 2.0×10⁴ Pa·s, a melt viscosity of the inorganic filler non-containing layer is 1.0×10³ to 2.0×10⁵ Pa·s, a viscosity difference between both layers is 1.5×10⁴ Pa·s or more; and a thickness of the inorganic filler non-containing layer is ⅓ to ⅘ of a height of the connecting electrode portion formed in the semiconductor element.

### BACKGROUND OF THE INVENTION

1. Field of the Invention

The present invention relates to an encapsulating resin sheet, which is used when a semiconductor element including a connecting electrode portion is mounted on an interconnection circuit substrate such as a mother board, a semiconductor device, which is a mounting body using the encapsulating resin sheet, and to a method of fabricating the semiconductor device.

2. Description of the Related Art

In a field of a semiconductor package, in which high-density mounting directed to mobile devices is required, flip-chip mounting is generally employed, which is a mounting method capable of down-sizing and thinning. The flip-chip mounting is a mounting method in which a terminal of the semiconductor element (chip) and a terminal of the interconnection circuit substrate face each other to be connected, and hence a connection failure is liable to occur due to thermal stress caused by a thermal expansion coefficient difference between the semiconductor element and the interconnection circuit substrate. For that reason, in the flip-chip mounting, generally, a thermosetting resin containing an inorganic filler is encapsulated into a terminal connecting portion between the semiconductor element and the interconnection circuit substrate, and reinforcing is performed with this encapsulation to disperse the stress, which is concentrated to a terminal connecting portion between the semiconductor element and the interconnection circuit substrate, thereby enhancing a connection reliability.

As a method of filling the thermosetting resin between the semiconductor element and the interconnection circuit substrate, currently and mainly employed is a method including, after bonding the semiconductor element onto the interconnection circuit substrate, injecting a liquid underfill between the semiconductor element and the interconnection circuit substrate. However, this method involves such a problem that a void is liable to be formed, when the above-mentioned injection is performed, due to a narrow gap accompanied by recent height reduction of the semiconductor package and multiplication of terminal pins. Therefore, as a method to solve such problem, in recent years, there is proposed a resin encapsulation method including: sandwiching an encapsulating resin sheet containing an inorganic filler between the semiconductor element and the interconnection circuit substrate; heat-melting the resin sheet to form an encapsulating resin layer; and compression-bonding through application of pressure between the terminals of the semiconductor element and the interconnection circuit substrate (for example, referred to Japanese Patent Application Laid-open No. 10-242211).

However, in the resin encapsulation technique using the encapsulating resin sheet, as described above, when the encapsulating resin sheet is sandwiched between the semiconductor element and the interconnection circuit substrate, an inorganic filler within the encapsulating resin sheet intrudes between the terminals of the semiconductor element and the interconnection circuit substrate, and thus a conductive characteristic is deteriorated, with the result that there is a fear of lowering connection reliability.

### SUMMARY OF THE INVENTION

Japanese Patent No. 3999840 discloses a method of suppressing the intrusion of the inorganic filler between the terminals of the semiconductor element and the interconnection circuit substrate. In the method, as the encapsulating resin sheet, a laminate of an inorganic containing layer and an inorganic non-containing layer is used, and a device is made so that a terminal connecting portion between the semiconductor element and the interconnection circuit substrate is positioned at the inorganic filler non-containing layer when the resin encapsulation is performed using the same. However, it is actually difficult to produce a state like this, in which the inorganic filler does not exist without fail between the terminals of the semiconductor element and the interconnection circuit substrate, thereby enhancing a bonding reliability.

An encapsulating resin sheet is provided having an improved connection reliability by improving a connection failure caused by a thermal expansion coefficient difference between a semiconductor element and an interconnection circuit substrate, and by suppressing intrusion of an inorganic filler between terminals of the semiconductor element and the interconnection circuit substrate, a semiconductor device using the same, and a fabricating method for the semiconductor device.

According to a first embodiment, there is provided an encapsulating resin sheet for a semiconductor device having mounted on an interconnection circuit substrate a semiconductor element in a state in which a connecting electrode portion formed in the semiconductor element and a connecting terminal formed on the interconnection circuit substrate face each other, the encapsulating resin sheet being used for resin-encapsulating a gap between the interconnection circuit substrate and the semiconductor element, the encapsulating resin sheet having a two-layer structure including: (α) an epoxy resin composition layer containing an inorganic filler; and (β) an epoxy resin composition layer which does not contain an inorganic filler, the (α) layer and the (β) layer having the following characteristics (x) to (z):
(x) at a laminate temperature selected from 60 to 125° C., a melt viscosity of the (α) layer is 1.0×10² to 2.0×10⁴ Pa·s, and a melt viscosity of the (β) layer is 1.0×10³ to 2.0×10⁵ Pa·s;
(y) a difference between the melt viscosity of the (β) layer and the melt viscosity of the (α) layer ((β) layer−(α) layer) is 1.5×10⁴ Pa·s or more; and
(z) a thickness of the (β) layer of the encapsulating resin sheet is ⅓ h to ⅘ h relative to a height (h) of the connecting electrode portion.

Further, according to a second embodiment, there is provided a semiconductor device having mounted on an interconnection circuit substrate a semiconductor element in a state in which a connecting electrode portion formed in the semiconductor element and a connecting terminal formed on the interconnection circuit substrate face each other, wherein a gap between the interconnection circuit substrate and a semiconductor element is resin-encapsulated by an encapsulating resin layer having a two-layer structure of an inorganic filler containing layer and an inorganic filler non-containing layer, the encapsulating resin layer including the encapsulating resin sheet according to the first embodiment, such that the inorganic filler containing layer is positioned on the semiconductor element side.

Still further, according to a third embodiment, there is provided a method of fabricating a semiconductor device, including: preparing an encapsulating resin sheet provided with a release sheet, the encapsulating resin sheet being formed by laminating the encapsulating resin sheet so that the (β) layer of the encapsulating resin sheet according to the first embodiment is directly laminated on one surface of a release sheet; bonding the encapsulating resin sheet onto a semiconductor element having a connecting electrode portion formed therein, by attaching and pressurizing the encapsulating resin sheet provided with a release sheet onto a surface of the semiconductor element; placing and pressurizing, after releasing the release sheet, the semiconductor device provided with the encapsulating resin sheet onto an interconnection circuit substrate having a connecting terminal formed thereon so that the connecting electrode portion formed in the semiconductor element and a connecting terminal formed on the interconnection circuit substrate face each other; and resin-encapsulating a gap between the interconnection circuit substrate and the semiconductor element by heat-curing the encapsulating resin sheet.

The encapsulating resin sheet disclosed prevents the lowering of the connection reliability caused by intrusion of an inorganic filler from occurring more than Japanese Patent No. 3999840. Then, the encapsulating resin sheet employs an epoxy resin composition sheet having a two-layer structure of an inorganic filler containing layer and an inorganic filler non-containing layer. The inorganic filler containing layer side of the encapsulating resin sheet, each layer thereof having the fusion viscosity and the thickness being set within specific ranges, is attached and pressurized onto a surface of the semiconductor element having a connecting electrode portion (bump) formed thereon, thereby bonding the encapsulating resin sheet onto the semiconductor element so that a tip portion of the bump penetrates the inorganic filler containing layer to be positioned within the inorganic filler non-containing layer; when bonding the terminal; a state which is free of the inorganic filler is formed without fail at near of a tip portion of the bump; and under this state, the inorganic filler non-containing layer side of the encapsulating resin sheet is pasted onto the interconnection circuit substrate having formed thereon a connecting terminal. Then, when the resin encapsulation is performed by heat-melting the encapsulating resin sheet and by compression-bonding between the semiconductor element and the interconnection circuit substrate, the intrusion of the inorganic filler can be prevented from occurring between the connecting electrode portion of the semiconductor element and the connecting terminal of the interconnection circuit substrate, with the result that a connection reliability may be enhanced and the connection failure caused by a thermal expansion coefficient difference between the semiconductor element and the interconnection circuit substrate may also be improved.

As described above, the encapsulating resin sheet is an epoxy resin composition sheet having a two-layer structure of the inorganic filler containing layer and the inorganic filler non-containing layer, the fusion viscosity of each layer (melt viscosity at laminate temperature selected from 60 to 125° C.) falls within a specific range, the difference between the fusion viscosities of both layers falls within a specific range, and the thickness of the inorganic filler non-containing layer falls within a specific range. Then, the encapsulating resin sheet is interposed at a predetermined position between the interconnection circuit substrate and the semiconductor element, the encapsulating resin sheet is resin-encapsulated by heat-melting and compression-bonding between the semiconductor element and the interconnection circuit substrate, and thus the intrusion of the inorganic filler between the connecting electrode portion of the semiconductor element and the connecting terminal of the interconnection circuit substrate can be prevented from occurring, with the result that a connection reliability may be enhanced and the connection failure caused by a thermal expansion coefficient difference between the semiconductor element and the interconnection circuit substrate may also be improved. Consequently, the lowering of a conductive characteristic between the semiconductor element and the interconnection circuit substrate may be suppressed, thereby being capable of obtaining the semiconductor device having a high reliability.

### BRIEF DESCRIPTION OF THE DRAWINGS

FIG. 1 is a sectional view illustrating an example of an encapsulating resin sheet.

FIG. 2 is an explanatory sectional view illustrating a production step of a semiconductor device.

FIG. 3 is an explanatory sectional view illustrating a production step of the semiconductor device.

FIG. 4 is an explanatory sectional view illustrating a production step of the semiconductor device.

FIG. 5 is an explanatory sectional view illustrating a production step of the semiconductor device.

FIG. 6 is a sectional view illustrating an example of a semiconductor device.

### DETAILED DESCRIPTION OF THE INVENTION

Next, exemplary embodiments of the present invention are described in detail.

An encapsulating resin sheet is, as described above, directed to a semiconductor device having mounted on an interconnection circuit substrate a semiconductor element in a state in which a connecting electrode portion formed in the semiconductor element and a connecting terminal formed on the interconnection circuit substrate face each other, and is used for resin-encapsulating a gap between the interconnection circuit substrate and the semiconductor element. Further, as illustrated in FIG. 1, an encapsulating resin sheet 1 has a two-layer structure including (α) an epoxy resin composition layer containing an inorganic filler (inorganic filler containing layer 3) and (β) an epoxy resin composition layer which does not contain an inorganic filler (inorganic filler non-containing layer 2), and the (α) layer and the (β) layer each has the following characteristics (x) to (z). It should be noted that a melt viscosity in the following characteristic (x) may be measured using a general rheometer. However, for example, the melt viscosity may measured by using a rotational viscometer (RHEOSTRESS RS1 manufactured by HAKKE) under conditions of a gap: 100 μm; a rotating cone diameter: 20 mm; and a rotational speed: 10 s⁻¹.

(x) At a laminate temperature selected from 60 to 125° C., a melt viscosity of the (α) layer is 1.0×10² to 2.0×10⁴ Pa·s, and a melt viscosity of the (β) layer is 1.0×10³ to 2.0×10⁵ Pa·s.

(y) A difference between the melt viscosity of the (β) layer and the melt viscosity of the (α) layer ((β) layer−(α) layer) is 1.5×10⁴ Pa·s or more.

(z) A thickness of the (β) layer of the encapsulating resin sheet is ⅓ h to ⅘ h relative to a height (h) of the connecting electrode portion.

When the encapsulating resin sheet is used, from the view point of preventing the intrusion of an inorganic filler between the terminals of the semiconductor element and the interconnection circuit substrate, thereby enhancing the connection reliability, in the above-mentioned characteristic (x), the melt viscosity of the (α) layer preferably falls within a range of from 5.0×10² to 1.0×10³ Pa·s, the melt viscosity of the (β) layer preferably falls within a range of from 1.0×10⁴ to 2.0×10⁵ Pa·s.

Further, from the same points of view, in the above-mentioned characteristic (y), the difference between the melt viscosity of the (β) layer and the melt viscosity of the (α) layer ((β) layer−(α) layer) preferably falls within a range of from 1.5×10⁴ to 2.0×10⁵ Pa·s.

Further, from the same points of view, in the above-mentioned characteristic (z), the thickness of the (β) layer preferably falls within a range of from ½ h to ⅔ h relative to the height (h) of the connecting electrode portion formed in the semiconductor element.

In addition, in the encapsulating resin sheet, from the same points of view, the thickness of the (α) layer is preferably ½ h to ⅔ h relative to the height (h) of the connecting electrode portion.

It should be noted that the height (h) of the connecting electrode portion generally falls within a range of from 10 to 200 μm. Accordingly, the thickness of the (α) layer and the thickness of the (β) layer each are determined based on this value.

As materials for forming the (α) layer, preferably used is an epoxy resin composition containing an epoxy resin, a phenol resin, an elastomer component, and an inorganic filler, and as materials for forming the (β) layer, preferably used is an epoxy resin composition containing an epoxy resin, a phonemic resin, and an elastomer component. Further, as the materials for forming the respective layers, a curing accelerator, a flame retardant, a pigment including a carbon black, or the like, or another additive may be blended thereto.

As the epoxy resin, specifically, a naphthalene-type epoxy resin, a trisphenol-type epoxy resin, a bisphenol A-type epoxy resin, or the like may be used. Besides, as the phenol resin, specifically, an aralkyl-type phenolic resin, a phenol novolak resin, or the like may be used. Further, as the elastomer component, specifically, a copolymer of ethylene-acrylic acid, butyl acrylate, and acrylonitrile may be used. As the inorganic filler, specifically, quartz glass, talc, silica (fused silica, crystalline silica, etc.), or powders such as alumina, aluminium nitride, and silicon nitride may be used.

Then, as illustrated in the above-mentioned characteristic (x), as a method of adjusting the melt viscosities of the (α) layer and the (β) layer, for example, there is a method involving adjusting an amount of elastomer or an amount of the inorganic filler within the forming material of each layer. However, from the viewpoint of achieving lower linear thermal expansion for thermal stress reliability, it is preferred to adjust the amount of elastomer. Then, in order to satisfy the above-mentioned characteristic (x), it is preferred that the amount of elastomer within the forming material of the (α) layer be set to 1 wt % or more and less than 20 wt %, and the amount of elastomer within the forming material of the (β) layer be set to 20 wt % or more and less than 50 wt %, from the view point of achieving ease of viscosity adjustment.

The encapsulating resin sheet may be produced, for example, as follows.

Specifically, first, the resin compositions, which are the materials of the (α) layer and the (β) layer, are each mixed and prepared until the respective blended components are uniformly dispersed and mixed. Then, the resin composition thus prepared is formed into a sheet shape. As this formation method, for example, there are exemplified a method involving extrusion-molding the resin composition thus prepared into a sheet shape, and a method involving dissolving or dispersing the resin composition thus prepared into an organic solvent, or the like to prepare a varnish, and coating the varnish on a base such as polyester, followed by drying, thereby obtaining the resin composition sheet. Of those, from the view point of being capable of easily obtaining a sheet having a uniform thickness, the formation method involving coating of the varnish is preferred. It should be noted that a release sheet such as a polyester film may optionally be pasted on the surface of the resin composition sheet thus formed to protect the surface of the resin composition sheet, and may be peeled off at the time of encapsulation. Further, as the above-mentioned base such as polyester, the release sheet may be adopted therefor.

As the organic solvent, which is used when the varnish is prepared, there may be used, for example, methyl ethyl ketone, acetone, cyclohexanone, dioxane, diethyl ketone, toluene, ethyl acetate, or the like. Those may be used alone or in combination of two kinds or more. Further, generally, it is preferred that the organic solvent be used so that a solid concentration of the varnish falls within a range of from 30 to 60 wt %.

The sheet-like epoxy resin compositions thus obtained, which correspond to the (α) layer and the (β) layer, are laminated, and are employed as the encapsulating resin sheet.

A semiconductor device may be fabricated using the encapsulating resin sheet, for example, as follows. More specifically, first, an encapsulating resin sheet provided with the release sheet is prepared, the encapsulating resin sheet being formed by laminating the encapsulating resin sheet so that the (β) layer of the encapsulating resin sheet is directly laminated on one surface of the release sheet. Next, the encapsulating resin sheet provided with a release sheet is pasted onto the semiconductor element having a connecting electrode portion formed therein, by attaching and pressurizing the encapsulating resin sheet provided with a release sheet onto a surface of the semiconductor element having a connecting electrode portion formed therein. Subsequently, after releasing the release sheet, the semiconductor device provided with the encapsulating resin sheet is placed and pressurized onto an interconnection circuit substrate having a connecting terminal formed thereon so that the connecting electrode portion formed in the semiconductor element and a connecting terminal formed on the interconnection circuit substrate face each other. Then, a gap between the interconnection circuit substrate and the semiconductor element is resin-encapsulated by heat-curing the encapsulating resin sheet.

The semiconductor device thus obtained is a semiconductor device having mounted on an interconnection circuit substrate a semiconductor element in a state in which a connecting electrode portion formed in the semiconductor element and a connecting terminal formed on the interconnection circuit substrate face each other, in which a gap between the interconnection circuit substrate and a semiconductor element is resin-encapsulated by an encapsulating resin layer having a two-layer structure of an inorganic filler containing layer and an inorganic filler non-containing layer, the encapsulating resin layer including the encapsulating resin sheet, such that the inorganic filler containing layer is positioned on the semiconductor element side.

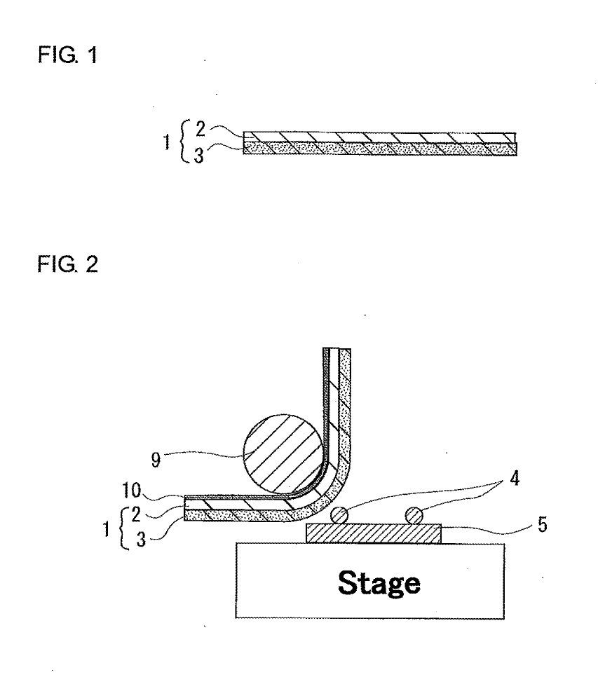

The production step of the above-mentioned semiconductor device is, specifically, carried out in a step order as illustrated in FIG. 2 to FIG. 6.

In other words, first, as illustrated in FIG. 2, the surface of the inorganic filler containing layer 3 ((α) layer) of the encapsulating resin sheet 1 is pasted using a roll laminator (roll 9) with respect to a placement surface of connecting electrode portions 4 on a semiconductor element 5 placed on a stage. The temperature of the stage at the time of bonding is a laminate temperature, and is a temperature selected from 60 to 125° C. at which the inorganic filler containing layer 3 ((α) layer) and the inorganic filler non-containing layer 2 ((β) layer) each indicate a specific viscosity range. It should be noted that, when the release sheet (polyester film, etc.) exists on the surface of the inorganic filler containing layer 3 ((α) layer), the bonding is carried out after being peeled off. Further, a lamination pressure is preferably 0.1 to 1 Mpa so that the tip portions of the connecting electrode portions 4 of the semiconductor element 5 may penetrate the inorganic filler containing layer to be positioned at the inorganic filler non-containing layer 2.

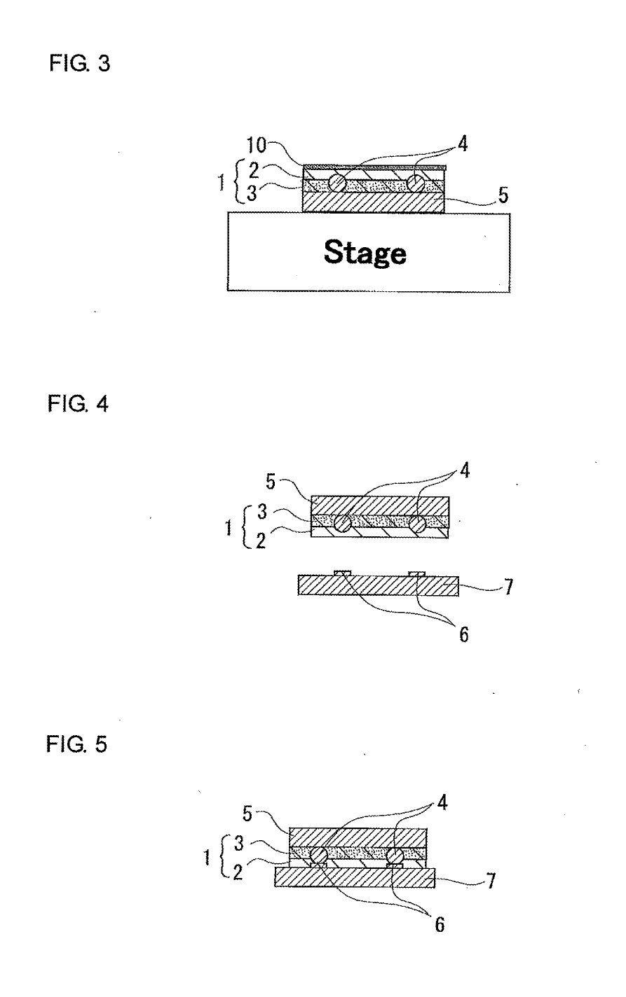

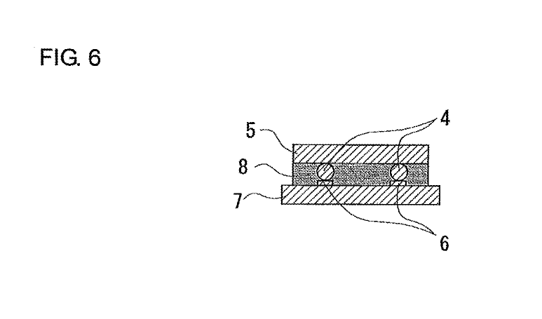

When the pasting is carried out as described above, and cutting of the encapsulating resin sheet 1 is carried out, a state as illustrated in FIG. 3 is obtained. It should be noted that the cutting of the encapsulating resin sheet 1 may be carried out before the above-mentioned bonding, and further, as described later, the cutting may be carried out simultaneously with a dicing step which is performed when the semiconductor element 5 is in a wafer. Subsequently, a release sheet 10 (polyester film, etc.) on the inorganic filler non-containing layer 2 side of the encapsulating resin sheet 1 thus pasted, is peeled off, and the surface of the inorganic filler non-containing layer 2, which is exposed thereby, is pasted, as illustrated in FIG. 4, onto placement surfaces of connecting terminals 6 on the interconnection circuit substrate 7. Subsequently, a predetermined pressure and heat are applied by using a flip-chip bonder (manufactured by Panasonic Corporation), or the like, as illustrated in FIG. 5, the bonding of the connecting electrode portions 4 of the semiconductor element 5 and the connecting terminals 6 of the interconnection circuit substrate 7 is carried out. As the bonding conditions, it is preferred that a bonding pressure (load per connecting electrode portion) be 0.0196 to 0.98 N/bump (0.002 to 0.1 kgf/bump), a bonding temperature be 260 to 290° C., and a bonding period be 2 to 20 seconds. With this, the encapsulating resin sheet 1 is melted and then heat-cured to be resin-encapsulated. As illustrated in FIG. 6, a resin-cured body 8 is obtained. Like this, the semiconductor element and the interconnection circuit substrate 7 are bonded to obtain a semiconductor device.

It should be noted that, when the semiconductor element 5 is in a wafer, a back grinding step and a dicing step are added between the step as illustrated in FIG. 3 and FIG. 4. That is, after the back grinding process and the dicing process with respect to the wafer are performed, the release sheet 10 on the inorganic filler non-containing layer 2 side is peeled off.

### EXAMPLES

Next, descriptions are made of Examples together with Comparative Examples. However, the present invention is not limited by these Examples.

First, as materials for forming an encapsulating resin sheet, the below-mentioned epoxy resins, phenolic resins, elastomers, a curing accelerator, and an inorganic filler are prepared.

<Epoxy Resin A>

A naphthalene-type epoxy resin having a hydroxyl equivalent of 142 g/eq (Product name: HP4032D (manufactured by DIC Corporation))

<Epoxy Resin B>

A trisphenylmethane-type epoxy resin having a hydroxyl equivalent of 169 g/eq (Product name: EPPN501HY (manufactured by Nippon Kayaku Co., Ltd.))

<Epoxy Resin C>

A bisphenol-type epoxy resin having a hydroxyl equivalent of 185 g/eq (Product name: YL-980 (manufactured by Japan Epoxy Resin Co., Ltd.))

<Phenol Resin A>

An aralkyl-type phenolic resin having a hydroxyl equivalent of 175 g/eq (Product name: MEHC-7800S (manufactured by Meiwa Plastic Industries, Ltd.))

<Phonemic Resin B>

A phenol novolak resin having a hydroxyl equivalent of 105 g/eq (Product name: CS-180 (manufactured by Gun Ei Chemical Industry Co., Ltd.))

<Elastomer A>

A copolymer of ethylene-acrylic acid, butyl acrylate, and acrylonitrile having a weight-average molecular weight of 450000 (glass transition temperature: −15° C.)

<Elastomer B>

A copolymer of ethylene-acrylic acid, butyl acrylate, and acrylonitrile having a weight-average molecular weight of 450000 (glass transition temperature: 15° C.)

<Curing Accelerator>

Triphenylphosphine (Product name: TPP-K (manufactured by Hokko Chemical Industry Co., Ltd.))

<Inorganic Filler>

Spherical fused silica having an average particle diameter of 0.5 μm (Product name: SE-2050 (manufactured by Admatechs Co., Ltd.))

<Production of Thermosetting Resin Composition Sheet>

The above-mentioned respective materials are blended in a ratio indicated in the following Table 1 (ratio of respective materials indicated in Compositions 1 to 11 in Table 1), and methyl ethyl ketone is added thereto, followed by mixing and dissolving. The resulting mixture solution is coated on a polyester film having subjected to releasing processing. Next, the polyester film on which the mixture solution is coated is dried at 110° C. to remove the methyl ethyl ketone. With this, a thermosetting resin composition sheet, which is formed of any one of Compositions 1 to 11, and has a predetermined thickness, is produced on the polyester film. It should be noted that, as illustrated in the following Table 1, a sheet, which is formed of any one of Compositions 1 to 5, constitutes the inorganic filler containing layer ((α) layer), and a sheet, which is formed of Compositions 6 to 11, constitutes the inorganic filler non-containing layer ((β) layer).

TABLE 1
(parts by weight)

| | | Compo- | Compo- | Compo- | Compo- | Compo- | Compo- | Compo- | Compo- | Compo- | Compo- | Compo- |
|---|---|---|---|---|---|---|---|---|---|---|---|---|
| | | sition 1 | sition 2 | sition 3 | sition 4 | sition 5 | sition 6 | sition 7 | sition 8 | sition 9 | sition 10 | sition 11 |
| Epoxy | A | — | — | — | — | — | 31.6 | — | 31.6 | 31.6 | 31.6 | 31.6 |
| resin | B | 24.3 | 38.1 | 33.2 | 28.3 | 14.8 | 7.9 | 28.3 | 7.9 | 7.9 | 7.9 | 7.9 |
| | C | 24.3 | — | — | — | 34.4 | — | — | — | — | — | — |
| Phenol | A | 22.9 | — | — | — | 22.6 | 11.8 | — | 11.8 | 11.8 | 11.8 | 11.8 |
| resin | B | 15.2 | 40.8 | 38.6 | 30.3 | 15.1 | 35.5 | 30.3 | 35.5 | 35.5 | 35.5 | 35.5 |
| Elastomer | A | 12.0 | — | — | — | — | 12.0 | — | 12.0 | 12.0 | 6.0 | 4.0 |
| | B | — | 20.0 | 30.0 | 40.0 | 12.0 | — | 40.0 | — | — | — | — |

| | | | | | | | | | | | |
|---|---|---|---|---|---|---|---|---|---|---|---|
| Curing | 1.2 | 1.2 | 1.2 | 1.2 | 1.2 | 1.2 | 1.2 | 1.2 | 1.2 | 1.2 | 1.2 |
| accelerator | | | | | | | | | | | |
| Inorganic | — | — | — | — | — | 100 | 150 | 130 | 140 | 100 | 100 |
| filler | | | | | | | | | | | |

### Examples 1 to 9 and Comparative Examples 1 to 10

The thermosetting resin composition sheets produced in the above were pasted, while attaching a polyester film, in combination of the (α) layer and the (β) layer indicated in Table 2 and Table 3 below (thickness of each layer is shown in Table 2 and Table 3) together by respective surfaces of the resin composition sheets, to thereby produce an encapsulating resin sheet having a two-layer structure.

A polyester film (release sheet) on the (α) layer side of the encapsulating resin sheet thus produced was peeled off, and the surface of the (α) layer, which is exposed thereby, was pasted using a roll laminator (rolling speed: 0.1 m/min, rolling pressure: 0.5 Mpa, product name: DR3000II (manufactured by Nitto Seiki Co., Ltd.)) so as to be brought into contact with the placement surface of the bumps (connecting electrode portions) of the semiconductor element placed on the stage (refer to FIG. 2). It should be noted that the encapsulating resin sheet used for the pasting was cut in the same dimensions as the semiconductor element. Further, the temperatures of the stage (laminate temperature) at the time of pasting are as shown in Table 2 and Table 3. Further, the melt viscosities of the (α) layer and the (β) layer at the laminate temperature were measured using a rotational viscometer (RHEOSTRESS RS1 manufactured by HAKKE) under the conditions of a measured temperature: 130° C.; a gap: 100 μm; a rotation cone diameter: 20 mm; and a rotational speed: 10 s⁻¹. The measurement results were also shown in Table 2 and Table 3 below. Further, the bump of the semiconductor element is a solder bump, and the height of the bump is 60 μm.

Subsequently, a polyester film on the (β) layer side of the encapsulating resin sheet thus pasted (refer to FIG. 3) is peeled off, and the surface of the (β) layer, which is exposed thereby, was pasted onto the connecting terminal placement surface on the interconnection circuit substrate (refer to FIG. 4). Next, the bonding of the bumps in the semiconductor element and the connecting terminals on the interconnection circuit substrate was carried out using a flip-chip bonder (bonding pressure: 0.029 N/bump (0.003 kgf/bump); bonding temperature: 280° C.×10 seconds; stage temperature: 140° C.), which is manufactured by Panasonic Corporation) (refer to FIG. 5), and resin encapsulation was performed to obtain the semiconductor device (refer to FIG. 6).

In the fabricating process of the semiconductor device thus carried out, evaluation was performed based on the following criteria as to whether or not the criteria were well satisfied. The results thereof were shown together in Table 2 and Table 3 below.

<Evaluation of Pasting>

After pasting the encapsulating resin sheet onto the semiconductor element, its cross-section was observed using a microscope (digital microscope VHX-500, manufactured by Keyence Corporation) at a magnification of 1000 times. As a result, a case where no inorganic filler exists at the tip of the bump is evaluated as o, a case where the bump is completely buried into the (β) layer is evaluated as ⊚, and a case where the inorganic filler layer is observed at the tip of the bump is evaluated as X.

<Evaluation of Bonding>

After bonding the semiconductor element and the interconnection circuit substrate, its cross-section was observed using a microscope (digital microscope VHX-500, manufactured by Keyence Corporation) at a magnification of 1000 times. As a result, a case where no inorganic filler exists at the bonding portion between the bump of the semiconductor element and the connecting terminal of the interconnection circuit substrate was evaluated as 0, and a case where the inorganic filler layer was observed at the bonding portion was evaluated as x.

TABLE 2

| | | | Examples | | | | | | | | |
|---|---|---|---|---|---|---|---|---|---|---|---|
| | | | 1 | 2 | 3 | 4 | 5 | 6 | 7 | 8 | 9 |
| Sheets | Compositions | α layer | Compo- | Compo- | Compo- | Compo- | Compo- | Compo- | Compo- | Compo- | Compo- |
| | | | sition 6 | sition 6 | sition 6 | sition 6 | sition 10 | sition 11 | sition 6 | sition 6 | sition 6 |
| | | β layer | Compo- | Compo- | Compo- | Compo- | Compo- | Compo- | Compo- | Compo- | Compo- |
| | | | sition 2 | sition 2 | sition 2 | sition 2 | sition 2 | sition 2 | sition 3 | sition 3 | sition 4 |
| | Flow test | α layer | 12,000 | 1,500 | 1,500 | 1,500 | 1,170 | 636 | 12,000 | 1,500 | 450 |
| | viscosity at | β layer | 89,850 | 18,380 | 18,380 | 18,380 | 18,380 | 18,380 | 161,700 | 72,630 | 19.860 |
| | laminate | Viscosity | 77,850 | 16,880 | 16,880 | 16,880 | 17,210 | 17,744 | 149,700 | 71,130 | 19,410 |
| | temperature | difference | | | | | | | | | |
| | (Pa · s) | | | | | | | | | | |
| | Thickness | α layer | 60 | 60 | 40 | 30 | 30 | 30 | 60 | 60 | 60 |
| | (μm) | β layer | 20 | 20 | 30 | 40 | 40 | 40 | 20 | 20 | 20 |

| Laminate temperature (° C.) | | 65 | 75 | 75 | 75 | 75 | 75 | 65 | 75 | 100 |
|---|---|---|---|---|---|---|---|---|---|---|
| Evalua- | Pasting | ◯ | ◯ | ⊚ | ⊚ | ⊚ | ⊚ | ◯ | ◯ | ◯ |
| tion | Bonding | ◯ | ◯ | ◯ | ◯ | ◯ | ◯ | ◯ | ◯ | ◯ |

TABLE 3

| | | | Comparative Example | | | | | | | | | |
|---|---|---|---|---|---|---|---|---|---|---|---|---|
| | | | 1 | 2 | 3 | 4 | 5 | 6 | 7 | 8 | 9 | 10 |
| Sheets | Compositions | α layer | Compo- | Compo- | Compo- | Compo- | Compo- | Compo- | Compo- | Compo- | Compo- | Compo- |
| | | | sition 7 | sition 6 | sition 6 | sition 6 | sition 6 | sition 6 | sition 6 | sition 6 | sition 8 | sition 9 |
| | | β layer | Compo- | Compo- | Compo- | Compo- | Compo- | Compo- | Compo- | Compo- | Compo- | Compo- |
| | | | sition 1 | sition 4 | sition 5 | sition 3 | sition 3 | sition 2 | sition 2 | sition 4 | sition 2 | sition 2 |
| | Flow test | α layer | 190,000 | 53 | 450 | 12,000 | 1,500 | 12,000 | 1,500 | 450 | 7,688 | 11,750 |
| | viscosity at | β layer | 80 | 1,957 | 45 | 161,700 | 72,630 | 89,850 | 18,380 | 19,860 | 18,380 | 18,380 |
| | laminate | Viscosity | −189,920 | 1,904 | −405 | 149,700 | 71,130 | 77,850 | 16,880 | 19,410 | 10,692 | 6,630 |
| | temperature | difference | | | | | | | | | | |
| | (Pa · s) | | | | | | | | | | | |
| | Thickness | α layer | 60 | 60 | 60 | 60 | 60 | 60 | 60 | 60 | 30 | 30 |
| | (μm) | β layer | 20 | 20 | 20 | 10 | 10 | 10 | 10 | 10 | 40 | 40 |

| Laminate temperature (° C.) | | 110 | 120 | 100 | 65 | 75 | 65 | 75 | 100 | 75 | 75 |
|---|---|---|---|---|---|---|---|---|---|---|---|
| Evalua- | Pasting | X | X | X | X | X | X | X | X | X | X |
| tion | Bonding | X | X | X | X | X | X | X | X | X | X |

From the results of the tables above, in Examples, the (α) layer (inorganic filler containing layer) and the (β) layer (inorganic filler non-containing layer) of the encapsulating resin sheet satisfy the requirements (melt viscosity of a layer is 1.0×10² to 2.0×10⁴ Pa·s, melt viscosity of (β) layer is 1.0×10³ to 2.0×10⁵ Pa·s, viscosity difference between both layers is 1.5×10⁴ Pa·s or more, thickness of (β) layer is 20 to 48 μm (⅓ to ⅘ of bump height)), and hence in the above-mentioned evaluations of “pasting” and “bonding”, satisfactory results were obtained. As a result, it was found that the lowering of the connection reliability between the semiconductor element and the interconnection circuit substrate caused by the intrusion of the inorganic filler may be prevented from occurring.

Contrary to this, in Comparative Examples, as in Examples, the semiconductor encapsulation is performed using the encapsulating resin sheet formed of the (α) layer (inorganic filler containing layer) and the (β) layer (inorganic filler non-containing layer). However, one or both of the (α) layer and the (β) layer do not satisfy the requirements, and hence the evaluations of “pasting” and “bonding” result in inferior to Examples.

Although specific forms of embodiments of the instant invention have been described above and illustrated in the accompanying drawings in order to be more clearly understood, the above description is made by way of example and not as a limitation to the scope of the instant invention. It is contemplated that various modifications apparent to one of ordinary skill in the art could be made without departing from the scope of the invention.

What is claimed is:

1. An encapsulating resin sheet for a semiconductor device having mounted on an interconnection circuit substrate a semiconductor element in a state in which a connecting electrode portion formed in the semiconductor element and a connecting terminal formed on the interconnection circuit substrate face each other, the encapsulating resin sheet being used for resin-encapsulating a gap between the interconnection circuit substrate and the semiconductor element,
The encapsulating resin sheet comprising: a two-layer structure comprising:
(α) an epoxy resin composition layer containing an inorganic filler; and
(β) an epoxy resin composition layer which does not contain an inorganic filler,
wherein the (α) layer and the (β) layer having the following characteristics (x) to (z):
(x) at a laminate temperature selected from 60 to 125° C., a melt viscosity of the (α) layer is 1.0×10² to 2.0×10⁴ Pa·s, and a melt viscosity of the (β) layer is 1.0×10³ to 2.0×10⁵ Pa·s;
(y) a difference between the melt viscosity of the (β) layer and the melt viscosity of the (α) layer ((β) layer−(α) layer) is 1.5×10⁴ Pa·s or more; and
(z) a thickness of the (β) layer of the encapsulating resin sheet is ⅓ h to ⅘ h relative to a height (h) of the connecting electrode portion.

2. The encapsulating resin sheet according to claim 1, wherein the thickness of the (α) layer of the encapsulating resin sheet is ½ h to ⅔ h relative to the height (h) of the connecting electrode portion.

3. The encapsulating resin sheet according to claim 1,
wherein the (α) layer comprises an epoxy resin composition containing an epoxy resin, a phenol resin, an elastomer component, and an inorganic filler; and
wherein the (β) layer comprises an epoxy resin composition containing an epoxy resin, a phenol resin, and an elastomer component.

4. The encapsulating resin sheet according to claim 2,
wherein the (α) layer comprises an epoxy resin composition containing an epoxy resin, a phenol resin, an elastomer component, and an inorganic filler; and
wherein the (β) layer comprises an epoxy resin composition containing an epoxy resin, a phenol resin, and an elastomer component.

5. A semiconductor device comprising:
a semiconductor element mounted on an interconnection circuit substrate in a state in which a connecting electrode portion formed in the semiconductor element and a connecting terminal formed on the interconnection circuit substrate face each other,
wherein a gap between the interconnection circuit substrate and the semiconductor element is resin-encapsulated by an encapsulating resin layer having a two-layer structure of an inorganic filler containing layer and an inorganic filler non-containing layer, and
wherein the encapsulating resin layer comprises the encapsulating resin sheet according to claim 1, such that the inorganic filler containing layer is positioned on the semiconductor element side.

6. A semiconductor device comprising:
a semiconductor element mounted on an interconnection circuit substrate in a state in which a connecting electrode portion formed in the semiconductor element and a connecting terminal formed on the interconnection circuit substrate face each other,
wherein a gap between the interconnection circuit substrate and the semiconductor element is resin-encapsulated by an encapsulating resin layer having a two-layer structure of an inorganic filler containing layer and an inorganic filler non-containing layer, and
wherein the encapsulating resin layer comprises the encapsulating resin sheet according to claim 2, such that the inorganic filler containing layer is positioned on the semiconductor element side.

7. A semiconductor device comprising:
a semiconductor element mounted on an interconnection circuit substrate in a state in which a connecting electrode portion formed in the semiconductor element and a connecting terminal formed on the interconnection circuit substrate face each other,
wherein a gap between the interconnection circuit substrate and the semiconductor element is resin-encapsulated by an encapsulating resin layer having a two-layer structure of an inorganic filler containing layer and an inorganic filler non-containing layer, and
wherein the encapsulating resin layer comprises the encapsulating resin sheet according to claim 3, such that the inorganic filler containing layer is positioned on the semiconductor element side.

8. A method of fabricating a semiconductor device, comprising:
preparing an encapsulating resin sheet provided with a release sheet, the encapsulating resin sheet being formed by laminating the encapsulating resin sheet so that the (β) layer of the encapsulating resin sheet according to claim 1 is directly laminated on one surface of a release sheet;
bonding the encapsulating resin sheet onto a semiconductor element having a connecting electrode portion formed therein, by attaching and pressurizing the encapsulating resin sheet onto a surface of the semiconductor element;
placing and pressurizing, after releasing the release sheet, the semiconductor device provided with the encapsulating resin sheet onto an interconnection circuit substrate having a connecting terminal formed thereon so that the connecting electrode portion formed in the semiconductor element and a connecting terminal formed on the interconnection circuit substrate face each other; and
resin-encapsulating a gap between the interconnection circuit substrate and the semiconductor element by heat-curing the encapsulating resin sheet.

9. A method of fabricating a semiconductor device, comprising:
preparing an encapsulating resin sheet provided with a release sheet, the encapsulating resin sheet being formed by laminating the encapsulating resin sheet so that the (β) layer of the encapsulating resin sheet according to claim 2 is directly laminated on one surface of a release sheet;
bonding the encapsulating resin sheet onto a semiconductor element having a connecting electrode portion formed therein, by attaching and pressurizing the encapsulating resin sheet onto a surface of the semiconductor element;
placing and pressurizing, after releasing the release sheet, the semiconductor device provided with the encapsulating resin sheet onto an interconnection circuit substrate having a connecting terminal formed thereon so that the connecting electrode portion formed in the semiconductor element and a connecting terminal formed on the interconnection circuit substrate face each other; and
resin-encapsulating a gap between the interconnection circuit substrate and the semiconductor element by heat-curing the encapsulating resin sheet.

10. A method of fabricating a semiconductor device, comprising:
preparing an encapsulating resin sheet provided with a release sheet, the encapsulating resin sheet being formed by laminating the encapsulating resin sheet so that the (β) layer of the encapsulating resin sheet according to claim 3 is directly laminated on one surface of a release sheet;
bonding the encapsulating resin sheet onto a semiconductor element having a connecting electrode portion formed therein, by attaching and pressurizing the encapsulating resin sheet onto a surface of the semiconductor element;
placing and pressurizing, after releasing the release sheet, the semiconductor device provided with the encapsulating resin sheet onto an interconnection circuit substrate having a connecting terminal formed thereon so that the connecting electrode portion formed in the semiconductor element and a connecting terminal formed on the interconnection circuit substrate face each other; and
resin-encapsulating a gap between the interconnection circuit substrate and the semiconductor element by heat-curing the encapsulating resin sheet.
